(19) United States
(12) Patent Application Publication
(10) Pub. No.: US 2006/0239098 A1
(43) Pub. Date: Oct. 26, 2006

(54) Dram architecture enabling refresh and access operations in the same bank

(75) Inventors: Toshio Sunaga, Ohtsu-shi (JP); Shinpei Wasanabe, Yokohama-shi (JP)

Correspondence Address: IBM MICROELECTRONICS;INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 11/424,861

(22) Filed: Jun. 17, 2006

Related U.S. Application Data
(62) Division of application No. 10/473,875, filed on Sep. 30, 2003, now Pat. No. 7,093,067.

(51) Int. Cl. G11C 7/00

(52) U.S. Cl. 365/222

(57) ABSTRACT

To provide a DRAM that reduces loss time of accesses at the time of refresh and performs refresh for any other bank in parallel with normal accesses and is able to be used just like SRAM. [Constitution]DRAM comprises: refresh directing means for directing execution of refresh; bank specifying means for specifying a bank address of the memory cells to be refreshed; addressing means for addressing a row address of the memory cells to be refreshed in the specified bank; and execution means for refreshing the memory cells of the row address addressed in the specified bank in response to the direction of execution of refresh from the refresh directing means.

### BACKGROUND OF INVENTION

1. Field of the Invention

The present invention relates to a DRAM (dynamic random access memory) having multiple banks and a method for refreshing the data stored in the DRAM.

2. Background of the Invention

For DRAM, there is a refresh scheme where row addresses are sequentially refreshed by updating them periodically using a refresh timer (RT) and a row address counter (RAC) as well as RAS-Only-Refresh (i.e., normal refresh). FIG. 1 illustrates a schematic diagram of this scheme. If there are multiple banks, RAC specifies a bank address R-bank and a row address R-row to be refreshed. A bank address R-bank output by RAC is input to a bank selector (BS) and a row address, R-row is input to a row selector (RS). Also input to BS is bank address (shown as Bank in FIG. 1) to be accessed that has been input to the address input (AI), while a row address (shown as Row in FIG. 1) to be accessed, that has been input to AI, is input to RS.

BS outputs either the bank address R-bank or bank, while RS outputs either the row address R-row or row. Selection of a combination of the bank and row outputs or the R-bank and R-row outputs is specified by RT. RT comprises a timer circuit and specifies R-bank and R-row outputs at predetermined time intervals. This indication is also input to a column enable (CE), where a column address is input that has been input to AI. CE temporarily stops column address output (i.e., column) while R-bank and R-row outputs are specified.

Either a bank, row address and column address to be accessed or a bank and row address to be refreshed are sent to a memory array. Since banks and row addresses common to the entire chip are switched, only one bank is accessible at a time. Therefore, in spite of the fact that there are a lot of banks that are not being accessed, they cannot be refreshed simultaneously. At the time of refresh, no access for normal reading and writing is performed and refresh is preferentially performed so that deterioration of availability of memory and deterioration of data rate occur.

It is therefore an object of the present invention to provide a DRAM that reduces access latency when refresh occurs.

### SUMMARY OF INVENTION

The present invention is directed to a DRAM where memory cells are accessed by specifying a bank address, row address and column address, the DRAM comprising: a refresh directing circuit for directing execution of refresh; a bank circuit for specifying a bank address of the memory cells to be refreshed; an addressing circuit for addressing a row address of the memory cells to be refreshed in the specified bank; and an execution circuit for refreshing the memory cells of the row address addressed in the specified bank in response to the direction of execution of refresh from the refresh directing integrated circuit. In parallel to normal read or write accesses the invention allows refresh operation to occur on banks not being accessed. Thus, the invention provides a structure and method to utilize the benefits of SRAM architecture within a DRAM circuit topology.

A method for refreshing a DRAM is disclosed where memory cells are accessed by specifying a bank address, row address and column address, the method comprising the steps of: directing execution of refresh of the memory cells; specifying a bank address of the memory cells to be refreshed; addressing a row address of the memory cells to be refreshed in the specified bank; and refreshing the memory cells of the row address addressed in the specified bank in response to the direction of execution of refresh.

### BRIEF DESCRIPTION OF DRAWINGS

FIG. 1 depicts a block diagram of configuration of conventional DRAM.

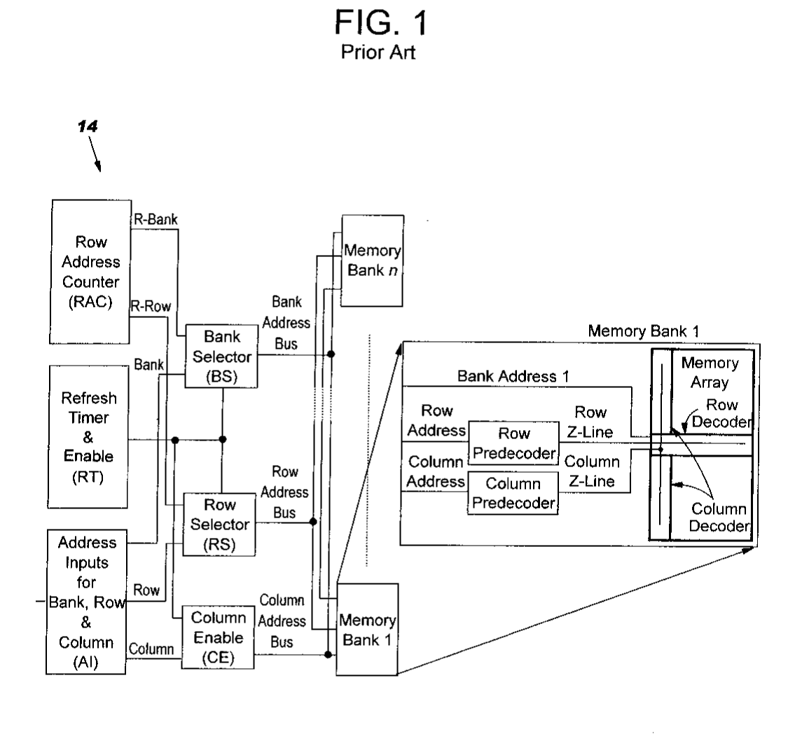

FIG. 2 depicts a block diagram of configuration of the DRAM of the present invention.

FIG. 3 depicts a circuit diagram of an example of a Z-line counter (ZLC).

FIG. 4 depicts a timing chart of the circuit shown in FIG. 3.

### DETAILED DESCRIPTION

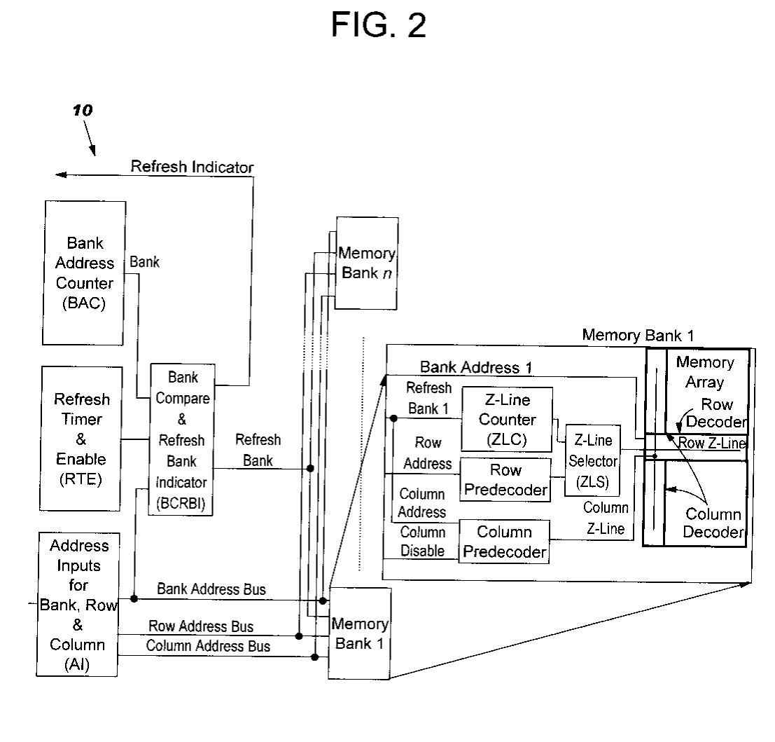

Now an embodiment of DRAM and a refresh method for DRAM according to the present invention will be described with reference to FIGS. 2, 3 and 4.

As shown in FIG. 2, DRAM 10 of the present invention comprises: refresh timer & enable (RTE) integrated circuit (i.e., refresh directing circuit) for directing execution of refresh; a bank address counter (BAC) (i.e., bank circuit) for specifying a bank address of memory cells to be refreshed; a Z-line counter (ZLC) (i.e., addressing circuit) for addressing a row address of the memory cells to be refreshed in the specified bank; and execution circuit for refreshing the memory cells of the row address addressed in the specified bank in response to the direction of execution of refresh from RTE.

The BAC logic block has an integrated circuit latch for holding the bank address of the memory cells to be refreshed; and an integrated circuit for updating the bank address held in the latch in response to the direction of execution of refresh from RTE.

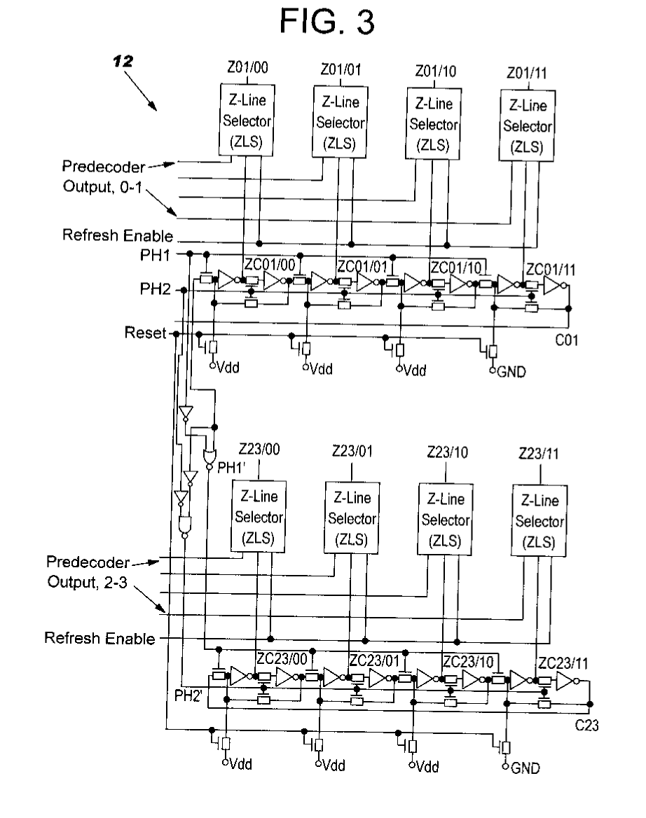

The ZLC logic block, shown in FIGS. 2 and 3, has an integrated circuit latch for holding the row address of the memory cells to be refreshed for each bank; and an integrated circuit for updating the row address held in the latch in response to the direction of execution of refresh from RTE.

The execution logic block, shown in FIG. 2, includes a bank compare & refresh bank indicator (BCRBI) for detecting a match between the bank address to be accessed and the bank address to be refreshed; a Z-line selector (ZLS) integrated circuit for selecting the row address to be accessed or the row address to be refreshed based on the match between the bank addresses; and a column predecoder (CP) for temporarily stopping addressing of the column addresses when the row address to be refreshed is selected.

According to DRAM 10 of the present invention, the row address to be accessed and the row address to be refreshed are selected by ZLS contained in the bank. The row address to be refreshed from ZLC and the row address to be accessed from a row predecoder (RP) are input to ZLS. The column address to be accessed is input to CP. The ZLC holds the row address to be refreshed, which is updated whenever refresh is performed. RP and CP hold the row address and column address to be accessed, respectively.

The row address and column address input to RP and CP, respectively, are sent from an address input for bank, row & column (AI). The bank address input to AI is sent to each memory bank, wherein the bank addressed is accessed. The bank address input to AI is also sent to BCRBI. BCRBI is supplied with a signal directing execution of refresh from RTE and a signal specifying a bank to be refreshed from BAC. BCRBI detects a match between the bank to be accessed and the bank to be refreshed. The result of the match detected is sent to ZLC and CP in each bank.

When the match is not detected, the bank to be refreshed and the bank to be accessed are specified by BCRBI. For the bank to be refreshed, the signal is sent to ZLC and CP, wherein CP temporarily stops the column address output while ZLS addresses the row address held in ZLC to refresh. For the bank to be accessed, the memory cells are accessed that are addressed by the row address output through RP and ZLS and the column address output from CP.

When the match is detected, the access and refresh are directed to the same bank. At this time, in order to perform the refresh, ZLS selects the row address to be refreshed while CP temporarily stops the column address output. While refresh is performed, the row address and column address to be accessed are held in RP and CP, respectively. When refresh is completed, the row address and column address to be accessed are output from RP and CP, respectively, then ZLS selects the row address to be accessed and then an access is performed. BCRBI sends a signal to the memory controller that the match between the banks has been detected.

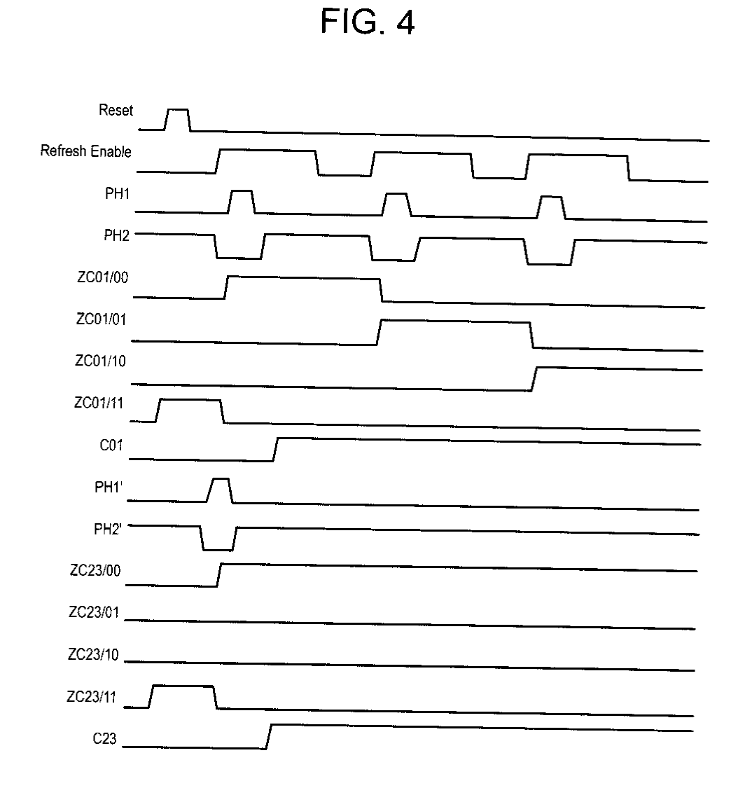

As shown in FIGS. 3 and 4, the predecoder generates four Z-lines using two bits TC of the address, wherein only one of four Z-lines is made high. When the address is counted up by one, the Z-line in high specified by the lower two address bits is shifted to an adjacent higher Z-line. This operates as a counter wherein Z-line in high is shifted every refresh.

FIG. 3 illustrates the lower four bits, and it is assumed that a similar circuit is provided in accordance with the total number of row address bits. Reset should initialize the counter to any address while most significant Z-line for each two bits, such as Z01/11 and Z23/11, is latched high. ZLC is incremented every refresh by lower two bits, while for higher bits thereof counting up is performed only when most significant Z-line is high.

In FIG. 4, PH1′ and PH2′ operate such that Z23/00 through Z23/11 increments only when most significant Z-line Z01/11 for lower bits is high. Therefore, Z01/11 and Z23/11 are selected to be high as an initial value. Note that PH2, PH2′ and PH1, PH1′ are non-overlap clocks that act on latch function and transfer function, respectively, wherein for the predecoder for lower two bits 0-1, a high level begins from Z01/11 and counts up (i.e., shifts) to Z01/00, Z01/01 and Z01/10 in sequence every refresh as shown in FIG. 4. For higher bits 2-3, counting up such as Z23/11 to Z23/00 is performed only when Z01/11 is high.

According to the aforementioned description, although a bank to be refreshed and timing for refresh are determined in the memory chip, these functions may be provided in the memory controller such that a bank to be refreshed and a bank to be accessed for reading and writing do not conflict with each other.

Next, a refresh method for the DRAM of the present invention will be described. A signal specifying a bank to be refreshed or a bank address, row address and column address externally accessed are supplied to a bank to be refreshed or to be accessed, respectively. An access to a bank specified by AI and refresh of a bank specified by BAC are performed simultaneously.

If the bank to be refreshed and the bank to be accessed match, refresh is preferentially performed. BCRBI informs the memory controller that the access is delayed for one cycle. While refresh is performed, a row address and column address are latched into RP and CP, respectively. When refresh is complete, an access is immediately performed to an address already latched.

In this way, refresh is performed in parallel with normal accesses. When a bank to be refreshed and a bank to be accessed match, refresh and an access are performed in sequence. At this time, the memory controller is informed that the access is delayed for one cycle. When an access to the same bank is continuously performed after refresh, timing for those accesses is delayed for one cycle as well. The effect of refresh operations on normal accesses is kept to a minimum latency, that is, one cycle of access delay due to refresh. As the number of banks increases, the probability of refresh of a bank conflicting with an external access to the same bank decreases, therefore, refresh will be performed while maintaining near zero loss of data transfer rate.

In summary, the present invention allows processing refresh nearly in parallel with data accesses so that refresh is transparent to external devices. Thus it appears as if refresh were not performed, so that the DRAM of the present invention may be used in a manner similar to conventional SRAM.

As mentioned above, according to the present invention, refresh is performed in parallel with normal accesses so that degradation of memory transfer rate due to refresh operations is reduced. Moreover, refresh operations are transparent to external devices, thus the DRAM of the present invention may be utilized like a conventional SRAM and is compatible with SRAM designs.

While the invention has been described in detail, the foregoing description is in all aspects illustrative and not restrictive. It is understood that numerous other modifications and variations can be devised without departing from the scope of the invention.

1. A DRAM where memory cells are accessed by specifying a bank address, row address and column address, comprising:
a refresh directing circuit that directs a refresh;
a bank circuit that specifies a bank address of the memory cells to be refreshed;
an addressing circuit that addresses a row address of the memory cells to be refreshed in the specified bank; and
an execution circuit that refreshes the memory cells of the row address addressed in the specified bank in response to the direction of execution of refresh from the refresh directing means.

2. The DRAM according to claim 1, wherein said bank circuit comprises:
a first latch that holds the bank address of the memory cells to be refreshed; and
an integrated circuit that updates the bank address held in said first latch in response to the direction of execution of refresh from said refresh directing circuit,
and wherein said addressing circuit comprises:
a second latch that holds the row address of the memory cells to be refreshed for each bank; and
a circuit that updates the row address held in said second latch in response to the direction of execution of refresh from said refresh directing circuit.

3. The DRAM according to claim 2, wherein said execution means comprises:
a circuit that detects a match between the bank address to be accessed and the bank address to be refreshed;
a circuit that selects the row address to be accessed or the row address to be refreshed based on the match between the bank addresses; and
a circuit that temporarily stops addressing of the column addresses when the row address to be refreshed is selected.

4. A method for refreshing a DRAM where memory cells are accessed by specifying a bank address, row address and column address, comprising the steps of:
directing execution of refresh of the memory cells;
specifying a bank address of the memory cells to be refreshed;
addressing a row address of the memory cells to be refreshed in the specified bank; and
refreshing the memory cells of the row address addressed in the specified bank in response to the direction of execution of refresh.

5. The method according to claim 4, wherein said bank specifying step comprises the steps of:
reading the bank address held in the first latch that holds the bank address of the memory cells to be refreshed in response to the direction of execution of refresh; and
updating the bank address held in the the first latch after the reading step,
and wherein said addressing step comprises the steps of:
reading the row address held in the second latch that holds the row address of the memory cells to be refreshed in response to the direction of execution of refresh; and
updating the row address held in the address holding means after the reading step.

6. The method according to claim 5, wherein said refreshing step comprises the steps of:
detecting a match between the bank address to be accessed and the bank address to be refreshed;
selecting the row address to be accessed or the row address to be refreshed based on the match between the bank addresses; and
temporarily stopping addressing of the column addresses when the row address to be refreshed is selected.

7. The method according to claim 6, wherein said selecting step comprises the steps of:
selecting and refreshing the row address;
after said refreshing step, selecting and accessing the row address to be accessed; and
notifying a memory controller that an access to the row address is delayed.
